(19) United States
(12) Patent Application Publication
(10) Pub. No.: US 2019/0369451 A1
(43) Pub. Date: Dec. 5, 2019

(54) ELECTRIC CIRCUIT BOARD

(71) Applicant: Japan Display Inc., Tokyo (JP)

(72) Inventors: Keita Sasanuma, Tokyo (JP); Yasushi Nakano, Tokyo (JP); Kengo Shiragami, Tokyo (JP); Takahiro Ochiai, Tokyo (JP)

(73) Assignee: Japan Display Inc., Tokyo (JP)

(21) Appl. No.: 16/426,562

(22) Filed: May 30, 2019

(30) Foreign Application Priority Data
May 30, 2018 (JP) 2018-103369
May 22, 2019 (JP) 2019-095813

(51) Int. Cl. G02F 1/1362; H05K 1/11; H05K 3/28

(52) U.S. Cl. CPC G02F 1/136286; H05K 3/28; H05K 1/117

(57) ABSTRACT

According to one embodiment, an electric circuit board includes a base material, a first terminal and a second terminal formed on the base material, a first wiring formed on the base material and connected to the first terminal, a second wiring formed on the base material and connected to the second terminal, a resin layer covering the first wiring and the second wiring, and a first pattern formed on the base material, the first terminal and the second terminal being arranged along a first direction, the first pattern being located between the first terminal and the second terminal, and the first pattern overlapping the resin layer in plan view.

### CROSS-REFERENCE TO RELATED APPLICATIONS

This application is based upon and claims the benefit of priority from Japanese Patent Applications No. 2018-103369, filed May 30, 2018; and No. 2019-095813, filed May 22, 2019, the entire contents of all of which are incorporated herein by reference.

### FIELD

Embodiments described herein relate generally to an electric circuit board.

### BACKGROUND

Display devices comprising a sensor to detect contacting or approaching of an object have been developed. In some of such display devices, detection electrodes are formed on a substrate which constitutes a display panel. In many cases, detection electrodes and wiring lines connected to the detection electrodes are covered by an overcoat layer for protection. On the other hand, terminal portions mounted on a wiring board or the like need to be exposed from the overcoat layer for electric connection. However, it is, in many cases, difficult to control (adjust) the position of the overcoat layer in the vicinities of the terminal portions.

### BRIEF DESCRIPTION OF THE DRAWINGS

FIG. 1 is a perspective view schematically showing a display device 1 according to the first embodiment.

FIG. 2 is a cross section showing a configuration example of a display panel shown in FIG. 1.

FIG. 3 is a plan view schematically showing a sensor 4 shown in FIG. 1.

FIG. 4 is a plan view schematically showing an example of each element provided on a second surface 20B of a substrate 20 shown in FIG. 2.

FIG. 5 is a plan view showing a vicinity of a wiring substrate 52 shown in FIG. 4.

FIG. 6 is a cross section taken along line VI-VI′ in FIG. 5.

FIG. 7 is an enlarged plan view terminals T11 and T12 shown in FIG. 5.

FIG. 8 is an enlarged plan view of dam portions DM1 and DM2 showing in FIG. 7.

FIG. 9 is a plan view showing a comparative example in the case where the dam portion DM1 is not provided between terminals T1.

FIG. 10 is a plan view showing another example of the dam portion DM1.

FIG. 11 is a plan view showing still another example of the dam portion DM1.

FIG. 12 is a plan view showing still another example of the dam portion DM1.

FIG. 13 is a plan view showing still another example of the dam portion DM1.

FIG. 14 is a plan view showing still another example of the dam portion DM1.

FIG. 15 is a plan view showing a configuration example of terminals T1 in a display device 1 according to the second embodiment.

FIG. 16 is a plan view showing another example of the terminals T1.

FIG. 17 is a plan view showing still another example of the terminals T1.

FIG. 18 is a plan view showing still another example of the terminals T1.

FIG. 19 is a plan view showing a display device 1 according to the third embodiment.

FIG. 20 is an enlarged view of a vicinity of a wiring substrate 52 shown in FIG. 19.

FIG. 21 is an enlarged plan view of terminals T11 and T12 shown in FIG. 20.

FIG. 22 is a plan view showing a configuration example of a terminal T1 of a display device 1 according to the fourth embodiment.

FIG. 23 is a plan view showing another example of the main portion MP.

FIG. 24 is a plan view showing another example of the main portion MP.

FIG. 25 is a plan view showing another example of the fourth embodiment.

### DETAILED DESCRIPTION

In general, according to one embodiment, an electric circuit board comprises a base material, a first terminal and a second terminal formed on the base material; a first wiring formed on the base material and connected to the first terminal, a second wiring formed on the base material and connected to the second terminal, a resin layer covering the first wiring and the second wiring; and a first pattern formed on the base material, the first terminal and the second terminal being arranged along a first direction, the first pattern being located between the first terminal and the second terminal, and the first pattern overlapping the resin layer in plan view.

According to another embodiment, an electric circuit board comprises a base material, a first terminal formed on the base material, a first wiring formed on the base material and connected to the first terminal, and a resin layer covering the first wiring, the first terminal comprising a main portion and a second pattern, the second pattern being located between the first terminal and the main portion, and is formed to be integrated with the main portion, and comprising a plurality of fifth openings, the main portion comprises a first area, and a second area located between the first area and the second pattern, the second area has a plurality of sixth openings smaller than the fifth openings, the fifth openings are formed of first portions extending along a first direction and second portions extending along a second direction crossing the first direction, the first portions has slit at a position between an adjacent pair of the fifth openings.

The embodiments will be described hereinafter with reference to the accompanying drawings. Note that the disclosure is presented for the sake of exemplification, and any modification and variation conceived within the scope and spirit of the invention by a person having ordinary skill in the art are naturally encompassed in the scope of invention of the present application. In addition, in some cases, in order to make the description clearer, the widths, thicknesses, shapes, etc., of the respective parts are schematically illustrated in the drawings as compared to the actual modes. However, the schematic illustration is merely an example, and adds no restrictions to the interpretation of the invention. In addition, in the specification and drawings, the structural elements, which have functions identical or similar to the functions described in connection with preceding drawings, are denoted by like reference numbers, and an overlapping detailed description thereof is omitted unless otherwise necessary.

### First Embodiment

In the present embodiment, a liquid crystal display device with detection function is disclosed as an example of the display device. For example, the liquid crystal display device can be used in various devices such as smartphones, tablet terminals, mobile phones, notebook computers, TVs, in-vehicle devices, and game consoles. Note that as the liquid crystal display device with detection function, other display devices are also applicable, such as a self-luminous display device with an organic electroluminescent (EL) element layer and an electronic-paper display device with an electrophoretic element.

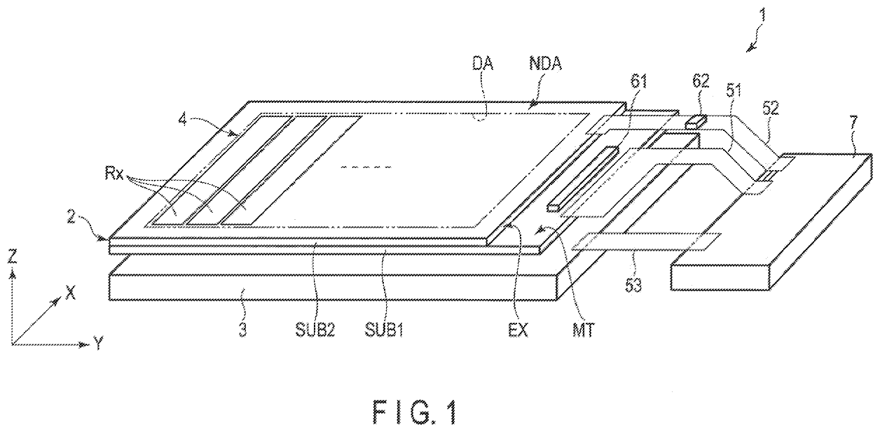

FIG. 1 is a perspective view schematically showing a display device 1 according to the first embodiment. In the drawing, a first direction X, a second direction Y and a third direction Z are orthogonal to each other. Note that the first direction X, the second direction Y, and the third direction Z may cross each other at an angle other than 90 degrees. In this specification, a direction towards a tip of an arrow indicating the third direction Z is referred to as “up”, and a direction opposite from the tip of the arrow is referred to as “down”. Further, an observation position where the display device 1 is observed is set on a tip end side of the arrow which indicates the third direction Z, and plan view is defined as a view from this observation position toward an X-Y plane defined by the first direction X and the second direction Y.

A display device 1 comprises a display panel 2, a backlight unit 3, a sensor 4, wiring substrates 51, 52 and 53, an IC chip 61, an IC chip 62, a control module 7 and the like.

The display device 2 is, for example, a liquid crystal display panel. The display panel 2 comprises a first substrate SUB1, a second substrate SUB2 and a liquid crystal layer LC held between the first substrate SUB1 and the second substrate SUB2. The first substrate SUB1 and the second substrate SUB2 oppose each other along the third direction Z. The second substrate SUB2 includes an end EX extending along the first direction X. The first substrate SUB1 includes a mount portion MT extending further from the end EX along the second direction Y.

The display panel 2 includes a display area DA which displays images and a non-display area NDA surrounding the display area DA. The display area DA is equivalent to an area where the first substrate SUB1 and the second substrate SUB2 overlap each other. In the example illustrated, the display area DA has substantially a rectangular shape with long sides along the second direction Y, but the shape of the display area DA is not limited to that of the example illustrated. The display panel 2 is, for example, a transmissive liquid crystal display panel which displays images by selectively transmitting light from the backlight unit 3.

The backlight unit 3 is disposed on a rear surface back side of the display panel 2, that is, directly under the first substrate SUB1. The backlight unit 3 is formed into substantially the same shape and size as those of the display panel 2. The backlight unit 3 illuminates an entire region of the display area DA. The backlight unit 3 can employ various structures, for example, one of which comprises a light guide opposing the first substrate SUB1 and a light source such as a light-emitting diode (LED) disposed at an end of the light guide.

The sensor 4 is, for example, a capacitive sensor. The sensor 4 comprises a plurality of detection electrodes Rx provided on the second substrate SUB2. In the example illustrated, the detection electrodes Rx are each formed into a belt shape extending along the first direction X and are arranged along the second direction Y. The second substrate SUB2 provided with the sensor 4 with such a configuration as described above, is equivalent to an electric circuit board.

A wiring substrate 51 is provided to electrically connect the display panel 2 and a control module 7 to each other. A wiring substrate 52 is provided to electrically connect at least part of the sensor 4 and the control module 7 to each other. A wiring substrate 53 is provided to electrically connect the backlight unit 3 and the control module 7 to each other. The wiring substrates 51, 52 and 53 each are a flexible printed circuit. An IC chip 61 is provided to drive the display panel 2. The IC chip 61 is mounted on the display panel 2. In the example illustrated, the IC chip 61 is mounted in the mount portion MT of the first substrate SUB1. An IC chip 62 is provided to drive the sensor 4. The IC chip 62 is mounted on the wiring substrate 52.

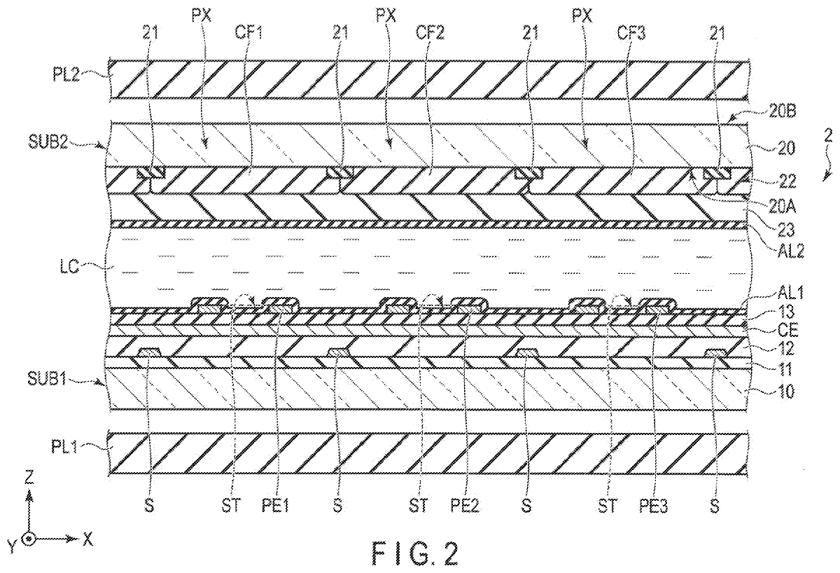

FIG. 2 is a cross section showing a configuration example of the display panel 2 shown in FIG. 1. The first substrate SUB1 comprises a base material 10, an insulating layer 11, an insulating layer 12, an insulating layer 13, signal lines S, a common electrode CE, pixel electrodes PE (PE1, PE2 and PE3), an alignment film AL1 and the like. The base material 10 is formed of, for example, a transparent insulating material such as glass or resin. The insulating layer 11 is formed on the base material 10. The signal lines S are formed on the insulating layer 11, and are covered by the insulating layer 12. The common electrode CE is formed on the insulating layer 12, and is covered by the insulating layer 13. The pixel electrodes PE are formed on the insulating layer 13, and are covered by the alignment film AL1. The pixel electrodes PE each are disposed in a region between each pair of signal lines S adjacent to each other along the first direction X, and each oppose the common electrode CE. In the example illustrated, each of the pixel electrodes PE comprises a slit ST. The pixel electrodes PE and the common electrode CE can be formed from, for example, a transparent conductive material such as indium tin oxide (ITO).

The second substrate SUB2 comprises a base material 20, light-shielding layers 21, color filter layers 22, an overcoat layer 23, an alignment film AL2 and the like. The base material 20 is formed of, for example, a transparent insulating material such as glass or resin. The second basement 20 comprises a first surface 20A opposing the first substrate SUB1, and a second surface 20B on an opposite side to the first surface 20A. The light-shielding layers 21 are formed on the first surface 20A of the base material 20. The light-shielding layers 21 each are provided to oppose a respective one of the signal lines S, thus partitioning the region into each pixel PX. Here, a pixel PX is equivalent to a minimum unit which can be individually controlled with respect to an image signal. The color filter layers 22 cover the light-shielding layers 21 and are also in contact with the base material 20. The color filter layers 22 include, for example, a red color filter CF1, a green color filter CF2 and a blue color filter CF3. The color filters CF1, CF2 and CF3 oppose pixel electrodes PE1, PE2 and PE3, respectively. The overcoat layer 23 covers the color filter layers 22. The overcoat layer 23 is formed of a transparent resin material. The alignment film AL2 covers the overcoat layer 23.

The liquid crystal layer LC is sealed between the first alignment film AL1 and the second alignment film AL2. The alignment film AL1 and the alignment film AL2 are, for example, horizontal alignment films which align liquid crystal molecules along a direction parallel to main surfaces of the base materials 10 and 20. The alignment of the liquid crystal molecules contained in the liquid crystal layer LC is controlled by the electric field formed between the common electrode CE and each pixel electrode PE. In this embodiment, the common electrode CE functions as an electrode of the sensor 4 as well as an electrode for driving the liquid crystal molecules.

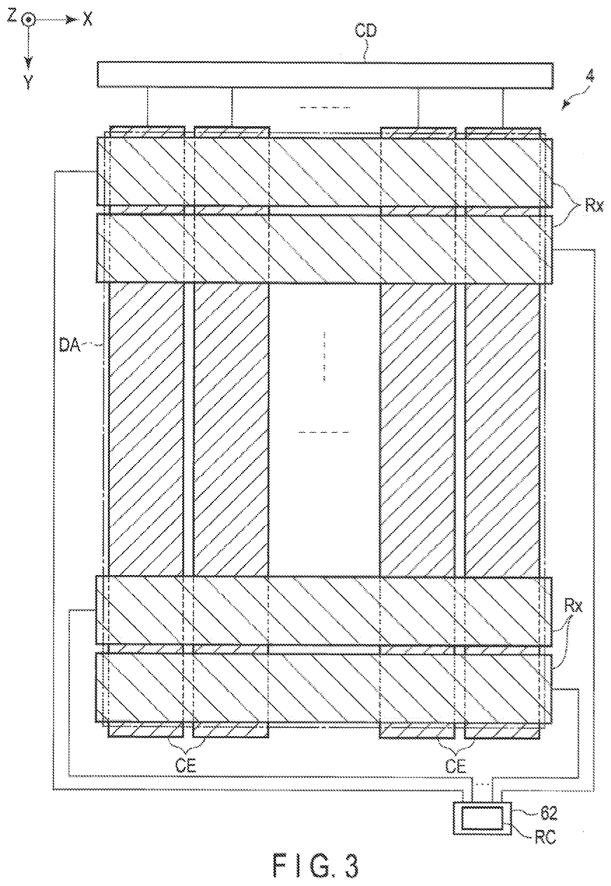

FIG. 3 is a plan view schematically showing the sensor electrode 4 shown in FIG. 1. The sensor 4 comprises detection electrodes Rx and common electrodes CE. The detection electrodes Rx each extend in a belt-like fashion along the first direction X and arranged along the second direction Y with constant gaps therebetween in the display area DA. The detection electrodes Rx are electrically connected to a detection circuit RC. The detection circuit RC is built in, for example, the IC chip 62. Note that the detection circuit RC may be built in the control module 7 shown in FIG. 1. On the other hand, the common electrodes CE each extend in a belt-like fashion along the second direction Y, and are arranged along the first direction X with constant gaps therebetween. The common electrodes CE are electrically connected to a common electrode drive circuit CD. The common electrode driver circuit CD is formed, for example, on the first substrate SUB1 in the non-display area NDA.

The common electrode driving circuit CD selectively supplies common drive signals for driving the pixels PX and sensor drive signals for driving the sensor 4, to the common electrodes CE. For example, the common electrode drive circuit CD supplies common drive signals to the common electrodes CE consecutively in display periods to display images on the display area DA. For example, the common electrode drive circuit CD supplies sensor drive signals to the common electrodes Tx in sensing periods to detect objects coming into contact with or approaching the display area DA.

In sensing periods, if a conductive object comes into contact with or approaches the display area DA, the capacitance formed between respective ones of the common electrodes CE and respective ones of the detection electrodes Rx located near the object varies. That is, a sensor output signal detected from the detection electrodes Rx located near the object indicates a value different from sensor outputs obtained from other detection electrodes Rx. The detection circuit RC detects that an object comes into contact with or approaches the display area DA based on the variation in the sensor output signals detected from the detection electrodes Rx. Further, the detection circuit RC specifies the location of the object coming into contact with or approaching the display area DA.

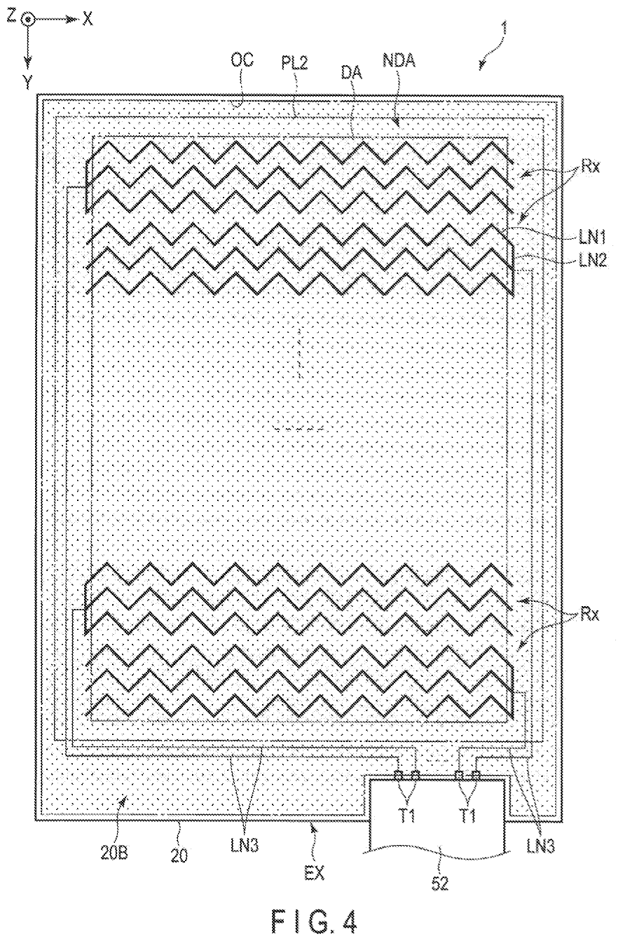

FIG. 4 is a plan view schematically showing each element provided on the second main surface 20B of the base material 20 shown in FIG. 2. The display device 1 comprises, in the second surface 20B, detection electrodes Rx, terminals T1, wiring lines LN3, a wiring substrate 52, a polarizer PL2 and an overcoat layer OC.

For example, the detection electrodes Rx include detection lines LN1 and a connection line LN2. The detection lines LN1 each is, in the display area DA, repeatedly bent into a wavy form, and extends along the first direction X. The contact line LN2 connects a plurality of detection lines LN1 of the detection electrode Rx in one end side. For example, the contact line LN2 is located in the non-display area NDA, and extends along the second direction Y. Note that the configuration of the detection electrodes Rx is not limited to that of the example illustrated. The detection electrodes Rx may be formed into, for example, a mesh.

Terminals T1 are formed in the non-display area NDA. In the example illustrated, the terminals T1 are arranged along the first direction X near an end portion EX of the second substrate SUB2 (here, an end of the base material 20). The terminals T1 are electrically connected to the respective detection electrodes Rx one by one by wiring lines LN3. In the example illustrated, the wiring lines LN3 are drawn out from the respective contact lines LN2 of the detection electrodes Rx, and are disposed in the non-display area NDA. The terminals T1, the wiring lines LN3 and the detection electrodes Rx are formed of a metal material such as molybdenum, tungsten, titanium or aluminum, and may be of a single or multilayer structure.

The wiring substrate 52 is mounted in a region which overlaps all the terminals T1. The wiring substrate 52 and the detection electrodes Rx are electrically connected to each other via the terminals T1.

The overcoat layer 23 covers substantially the entirely area of the second surface 20B except for the region where the wiring substrate 52 is formed. That is, the overcoat layer OC covers all of the detection electrodes Rx and the wiring lines LN3, and partially covers the terminals T1. The overcoat layer OC with such a structure is formed by, for example, applying a resin material on the second surface 20B by printing of the ink jet method (droplet discharging method) or the like, and then a heating process, followed by hardening the resin material.

The polarizer PL2 is provided on the overcoat layer 23. The polarizer PL2 entirely overlaps the display area DA. For example, the polarizer PL2 is rectangular and greater in size than that of the display area DA. In the example illustrated, the polarizer PL2 does not overlap the wiring lines LN3 in an end portion EX side of the non-display area NDA.

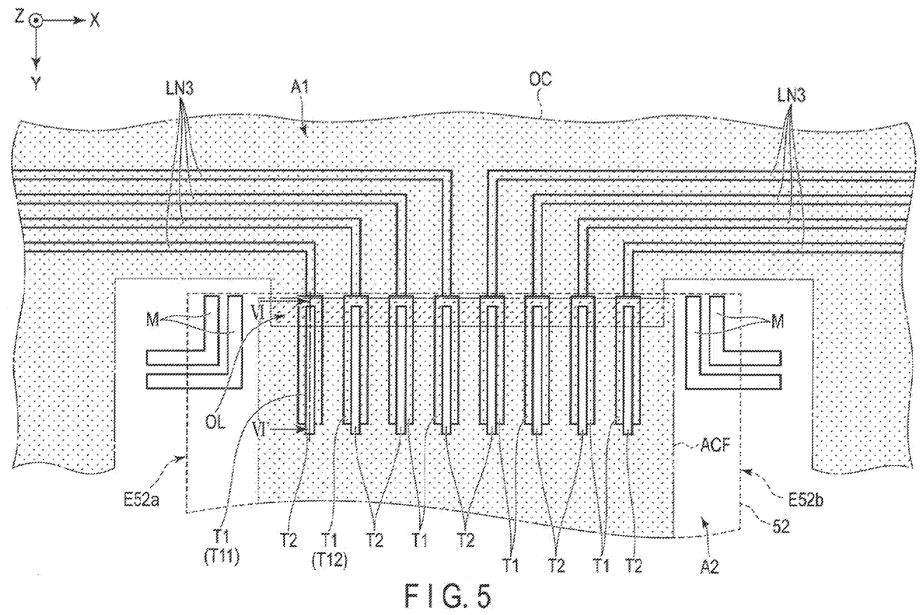

FIG. 5 is a plan view of a vicinity of the wiring substrate 52 shown in FIG. 4. Here, only the elements required for explanation are shown. FIG. 5 shows eight terminals T1 arranged at constant intervals along the first direction X, for example. A terminal T11 shown in this figure is one of the terminals T1, which is located at one end of the terminals T1, and is most close along the first direction X to an end portion E52a of the wiring substrate 52. A terminal T12 shown in this figure is one of the terminals T1, which is located next to the terminal T11, and is closer to the end E52b of the wiring substrate 52 than the terminal T11. Each of the terminals T1 extends in a belt-like fashion along the second direction Y. To the terminals T1, the wiring lines LN3 are connected respectively. In the example illustrated, two L-shaped alignment marks M are formed on outer sides of the terminals T1 located in both end portions. The alignment marks M are marks for aligning, used when mounting the wiring substrate 52. The alignment marks M with such structure can be formed by the same process and of the same material as those of the detection electrodes Rx, the terminals T1 and the wiring lines LN3.

The wiring substrate 52 comprises a plurality of terminals T2. The terminals T2 respectively oppose the terminals T1. That is, the terminals T2 are arranged at the same pitch as that of the terminals T1. The terminals T2 each extends in a belt-like fashion along the second direction Y. For example, the width of the terminal T2 along the first direction X is less than the width of the terminals T1 along the first direction X. In the example illustrated, each terminal T2 is located substantially in a central portion of each respective terminal T1 along the first direction X. On the other hand, along the second direction Y, the end portions of the terminals T2, on a side close to the wiring lines LN3 overlap the terminals T1, but the end portions of the terminals T2, on a side remote from the wiring lines LN3 do not overlap the terminals T1.

The wiring substrate 52 is connected to the base material 20 via an anisotropic conductive film ACF. Thus, a pair of a terminal T1 and a terminal T2 are electrically connected to each other. As indicated by an alternate long and two short dashes line shown in the figure, the anisotropic conductive film ACF is provided in the region roughly overlaps with the wiring substrate 52, and overlaps at least all the terminals T2.

As indicated by an alternate long and short dash line, the overcoat layer OC covers the wiring lines LN3 and partially overlaps the terminals T1 and T2. In the example illustrated, the overcoat layer OC does not overlap the alignment marks M. More specifically, the overcoat layer OC is disposed to surround a circumferential portion of the wiring substrate 52. The overcoat layer OC extends along the second direction Y in a region between the alignment marks M, and overlaps one end sides of the terminals T1 and T2. That is, the overcoat layer OC partially overlaps the anisotropic conductive film ACF and the wiring substrate 52.

In the following descriptions, the region which is covered by the overcoat layer OC but not covered by the anisotropic conductive film ACF is referred to as a first area A1. The region which is covered by the anisotropic conductive film ACF but not covered by the overcoat layer OC is referred to as a second area A2. Further, the region covered by both of the overcoat layer OC and the anisotropic conductive film ACF is referred to as an overlap area OL. In the example illustrated, the overlap area OL extends in a belt-like fashion along the first direction X.

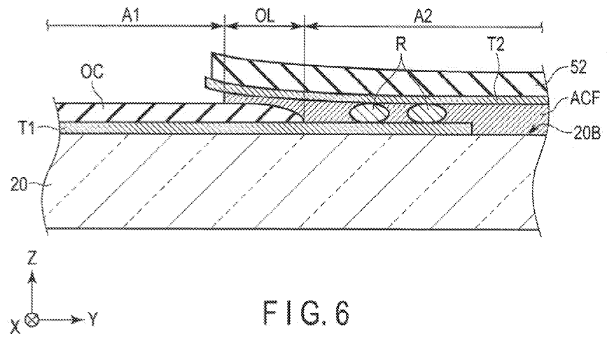

FIG. 6 is a cross section taken along line VI-VI′ in FIG. 5. A terminal T1 is formed on the second surface 20B of the base material 20. The overcoat layer OC is formed on the terminal T1 such as to partially expose the terminal. The portion of the terminal T1, which is exposed by the overcoat layer OC is electrically connected to the terminal T2 via the anisotropic conductive film ACF. The anisotropic conductive film ACF is an example of an electric conduction adhesive layer and contains conductive particles R in the adhesive. When the base material 20 and the wiring substrate 52 are pressurized to approach each other and then heated while interposing the anisotropic conductive film ACF between the terminal T1 and the terminal T2, the terminal T1 and the terminal T2 are connected electrically and physically to each other. Note that insulation between each pair of terminals T1 adjacent to each other in plan view, insulation between each adjacent pair of terminals T2 and insulation between each adjacent pair of terminal T1 and terminal T2 are maintained.

Generally, the adhesion between the terminal T1, which is formed of a metal material and the overcoat layer OC, which is formed of resin, is lower than the adhesion between the base material 20 formed of glass or resin and the overcoat layer OC. Therefore, in the proximity of the terminals T1, the detachment of the overcoat layer OC may adversely occur. Such detachment may occur when the wiring substrate 52 needs to be removed when manufacturing or repairing the display device 1. That is, when a force is applied to the wiring substrate 52 in a direction normal to the second surface 20B in order to remove the wiring substrate 52 from the display panel 2, the force in the normal direction is applied to the overcoat layer OC as well by the adhesive force of the anisotropic conductive film ACF in the overlap area OL. Here, the adhesion between the terminal T1 and the overcoat layer OC is weak, the overcoat layer OC may detach from the terminal T1 or the second surface 20B in the vicinity of the terminal T1.

In the case where the overlap area OL is not formed, the possibility that the overcoat layer OC detach becomes low, but undesirably, the terminal T1 may be partially exposed without being covered at all. In this case, moisture enters the terminal T1, possibly causing corrosion of the terminal T1. In order to prevent such corrosion, the overlap area OL should be formed.

Note that the problem of detachment of the overcoat layer OC is originated also from the structure the detection electrodes Rx are formed on the external surface (the second surface 20B of the base material 20) of the display panel 2. That is, in the formation process of the overcoat layer OC, the heat created when heating the resin material applied by printing may cause an adverse influence on the liquid crystal layer LC and the like, the temperature in the heating process cannot be sufficiently raised. As compared to an overcoat layer OC formed through a heating process of a high temperature (for example, about 220° C.), generally, an overcoat layer OC formed through a heating process of a low temperature (for example, about 120° C.) has low adhesion with respect to glass, resin material or metal material.

FIG. 6 is an enlarged plan view of terminals T11 and T12 shown in FIG. 5. In this embodiment, a dam portion DM1 is provided between each adjacent pair of terminals T1. The dam portion DM1 is spaced from both of the terminal T11 and the terminal T12. In the example illustrated, the dam portion DM1 is located in substantially a central part between the terminal T11 and the terminal T12 along the first direction X. The dam portion DM1 is formed into, for example, substantially a rectangular shape. In the example illustrated, the dam portion DM1 is formed into a mesh and comprises a plurality of openings OP1. The openings OP1 are linearly arranged along the first direction X. On the other hand, along the second direction Y, the openings OP1 are arranged in a staggered manner. The dam portion DM1 is formed of the same material as that of, for example, the terminals T1 and the wiring lines LN3.

The terminals T1 each include a main portion DM2 and a dam portion MP2. The main portion MP has substantially a rectangular shape with a pair of short sides extending along the first direction X and a pair of long sides extending along the second direction Y. The dam portion DM2 is located between a wiring line LN3 and a respective main portion MP to be connected thereto. Along the first direction X, the dam portion DM2 is located between each adjacent pair of dam portions DM1. That is, the dam portions DM1 and the dam portions DM2 are arranged along the first direction X. The dam portions DM2 are each formed into, for example, substantially a rectangular shape. A width WM of the main portion MP along the first direction X and a width WD2 of the dam portions DM2 along the first direction X are equal to each other. The dam portion DM2 is formed in a mesh and comprises a plurality of openings OP2. The openings OP2 are linearly arranged along the first direction X. On the other hand, along the second direction Y, the openings OP2 are arranged in a staggered manner.

As indicated by an alternate long and two short dashes line, the terminals T2 of the wiring substrate 52 overlaps both of the main portion MP and the main portions DM2. Along the second direction Y, one end portion of each terminal T2 overlaps the respective dam portion DM2, but does not overlap the respective wiring line LN3. An other end portion of each terminal T2 extends further in the second direction Y than the main portion MP.

The overcoat layer OC overlaps the wiring lines LN3, the dam portions DM1 and the dam portion DM2. On the other hand, the overcoat layer OC does not overlap the main portion MP. An end portion EOC of the overcoat layer OC is located in a range where the dam portions DM1 and DM2 are formed, along the second direction Y. In other words, along the second direction Y, end portions of the dam portions DM1 and DM2, which are on a side of the wiring lines LN3, are covered by the overcoat layer OC, but end portions on a side of the main portion MP are not covered by the overcoat layer OC.

The anisotropic conductive film ACF overlaps the main portion MP, the dam portions DM1 and the dam portions DM2. In the example illustrated, the anisotropic conductive film ACF overlaps substantially all of the main portion MP, the dam portions DM1 and the dam portions DM2. On the other hand, the anisotropic conductive film ACF does not overlap the wiring lines LN3.

Thus, the overlap area OL where the overcoat layer OC and the anisotropic conductive film ACF overlap each other is located in a range where dam portions DM1 and DM2 are formed, along the second direction Y.

As illustrated, it is preferable that not only each dam portion DM1 be disposed between each adjacent pair of terminals T1, but also a dam portion EDM be disposed on an opposite side to the terminals T12 with respect to the terminals T11. Here, the dam portion EDM is one of the terminals T1 and the dam portions DM1 arranged along the first direction X, which is located at an extreme end. In other words, of the terminals T1 and the dam portions DM1, the dam portion EDM is located most close to the end portion E52a the wiring substrate 52 shown in FIG. 5. With the dam portion EDM with such a structure being disposed near the terminals T11, it is possible to inhibit the overcoat layer OC from sneaking around a main portion MP side near the terminal T11. Note that it is preferable that a similar structure is formed near the end portion E52b of the wiring substrate 52 shown in FIG. 5.

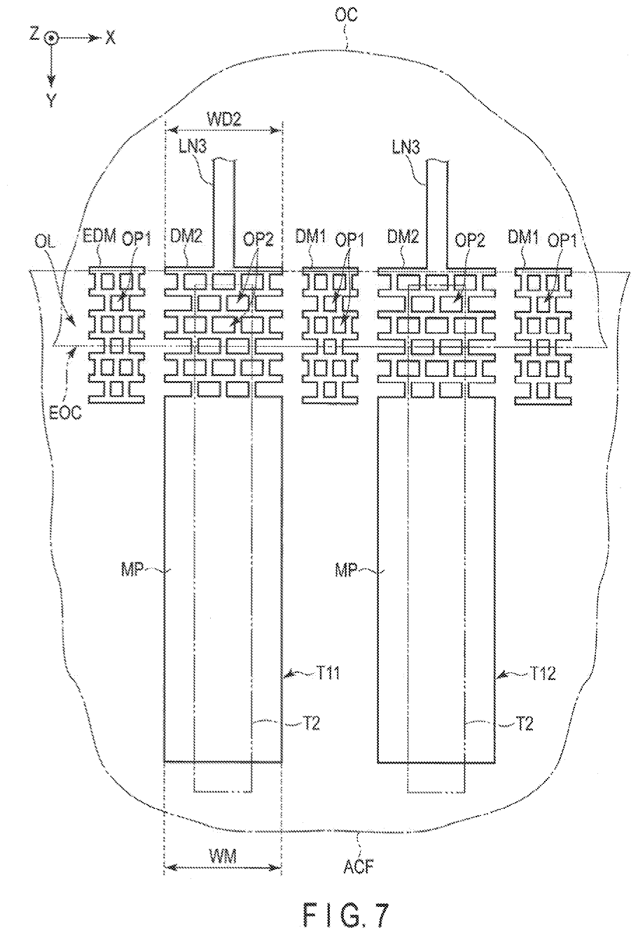

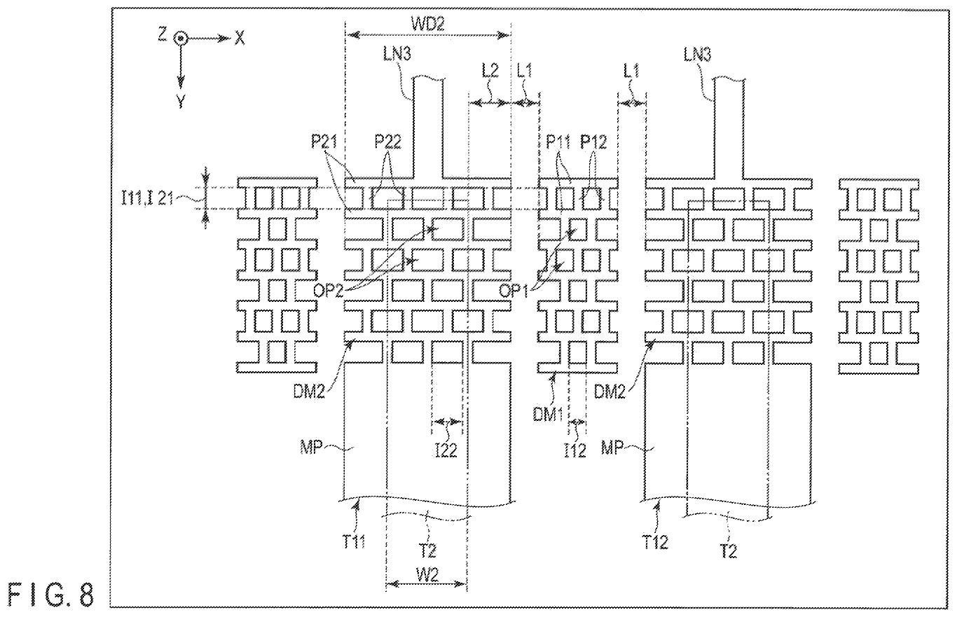

FIG. 8 is an enlarged plan view of dam portions DM1 and DM2 shown in FIG. 7. The dam portion DM1 is set distant at least by a distance L1 from both of the dam portion DM2 of the terminal T11 and the dam portion DM2 of the terminal T12. The distance L1 is such a distance that the insulation between each adjacent pair of terminals T1 is maintained when the wiring substrate 52 is mounted on the display panel 2 via the anisotropic conductive film ACF. The distance L1 is, for example, about 20 μm.

Moreover, a difference L2 in width shown in FIG. 8 is defined as a value of a half of the difference between the width WD2 of the dam portion DM2 and the width W2 of width WD2 of the terminals T2. Here, the widths WD2 and W2 are each defined along the first direction X. FIG. 8 shows a case where the width difference L2 is positive, that is, when the width W2 is less than the width WD2. In the case where the width difference L2 is negative, that is, when the width W2 is greater than the width WD2 and the terminals T2 extend along the first direction X further than the dam portion DM2, it is necessary to reserve, in addition to the distance L1, the distance L2 (an absolute value of the difference L2 in width) as an interval between each adjacent pair of terminals T2. Thus, the insulation between the adjacent terminals T2 is maintained.

In this embodiment, the structure of the dam portion DM1 and the structures of the dam portion DM2 are different from each other. For example, the mesh of the dam portion DM1 is denser than the mesh of the dam portion DM2. That is, the openings OP1 of the dam portion DM1 are smaller than the openings OP2 of the dam portion DM2.

More specifically, the dam portions DM1 each include a portion P11 extending along the first direction X and a portion P12 extending along the second direction Y. The portions P11 are arranged along the second direction Y with gaps I11 therebetween. The portions P12 are arranged along the first direction X with gaps I12 therebetween. The dam portions DM2 each include a portion P21 extending along the first direction X and a portion P22 extending along the second direction Y. The portions P21 are arranged along the second direction Y with gaps I21 therebetween. The portions P22 are arranged along the first direction X with gaps I22 therebetween. For example, the gaps I11 and the gaps I21 are equal to each other. In the example illustrated, the portions P11 and the portions P21 are arranged along the first direction X. On the other hand, the gaps I12 are less than the gaps I22. Therefore, the openings OP1 are smaller than the openings OP2.

Here, each of the gaps I11, I12, I21 and I22 is less than the pitch of the ink jet nozzles to form the overcoat layer OC. That is, projections and recesses created due to the mesh structure of the dam portions DM1 and DM2 are finer than the structure of the resin material discharged from the ink jet nozzles. For example, the gaps I11, I12, I21 and I22 are 50 μm or less. With such a structure, when the resin material discharged from the ink jet nozzles covers the dam portions DM1 and DM2, the tension acts to suppress the expansion of the resin material.

Note that the shape of dam portions DM1 is not limited to that of the example illustrated. As will be described later, it suffices if the dam portions DM1 each include at least the portion P11. That is, it suffices if the dam portions DM1 each comprise a member extending in a direction crossing a direction in which the resin material discharged from the ink jet nozzles expands (that is, the second direction Y).

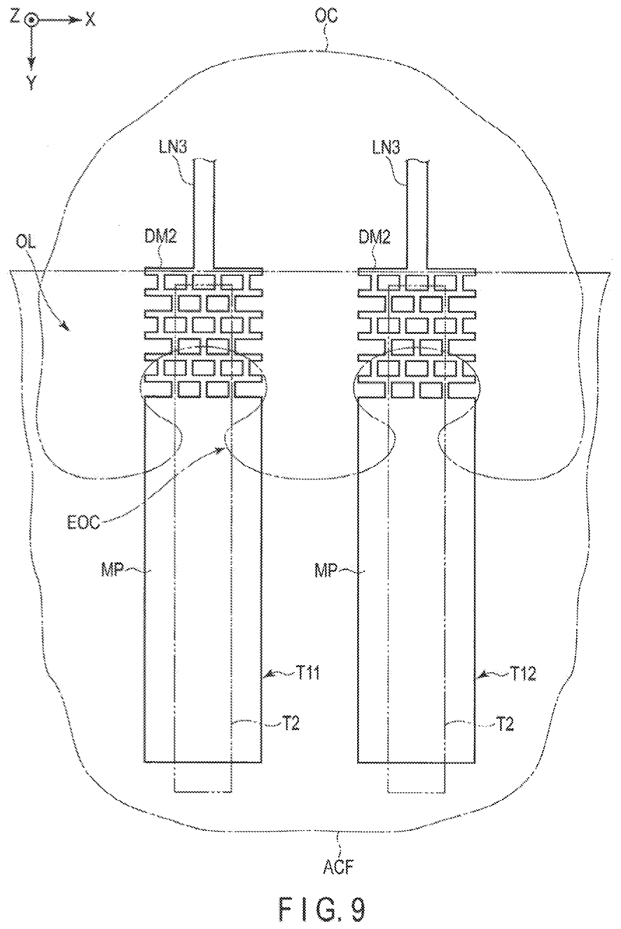

FIG. 9 is a plan view showing a comparative example where a dam portion DM1 is not provided between terminals T1. Generally, the base material 20 formed of glass or resin and the terminals T1 formed of a metal material are different from each other in the wettability to the overcoat layer OC. When the overcoat layer OC is formed by printing, the end EOC of the overcoat layer OC may be formed abnormally near the terminals T1 due to the difference in wettability between the second surface 20B and the terminal T1. When the wettability of the second surface 20B with respect to the overcoat layer OC is higher than the wettability of the terminals T1, it is assumed that the overcoat layer OC spreads over the region between the terminals T1 as shown in FIG. 9. Here, the effective connection area between the terminals T1 and the wiring substrate 52 decreases, and therefore the compression bonding between the display panel 2 and the wiring substrate 52 may be impaired and the resistance between the terminals T1 and the terminals T2 may be raised.

On the other hand, according to this embodiment, dam portions DM1 are each disposed between respective adjacent pair of terminals T1. With this structure, even if the resin material flows along the second direction Y when forming the overcoat layer OC, the resin material is dammed by the dam portions DM1. Thus, spreading of the overcoat layer OC to the region between the terminals T1 can be suppressed. As a result, attachment of the overcoat layer OC to the main portion MP is suppressed. That is, the effective connection area between the display panel 2 and the wiring substrate 52 is secured to improve the adhesion between the display panel 2 and the wiring substrate 52, and the rising of the connection resistance between the terminal T1 and the terminal T2 is suppressed. Therefore, a display device of high reliability can be provided. This embodiment is effective particularly when the gaps between the terminals T1 are large, that is, for example, the gap between adjacent pair of terminals T1 is 100 μm or greater.

Furthermore, according to this embodiment, the variation in the position of the end portion EOC of the overcoat layer OC can be lessened. That is, along the second direction Y, the end portion EOC is controlled to be located within the range where the dam portions DM1 and DM2 are formed. Thus, the area of the overlap area OL can be decreased. Consequently, it is possible to reduce the width of the frame of the display device 1.

Moreover, the dam portions DM1 and DM2 comprise the openings OP1 and OP2, respectively. With this structure, the contact area between the base material 20 and the overcoat layer OC is secured near the terminals T1. Therefore, near the terminals T1, the detachment of the overcoat layer OC can be suppressed.

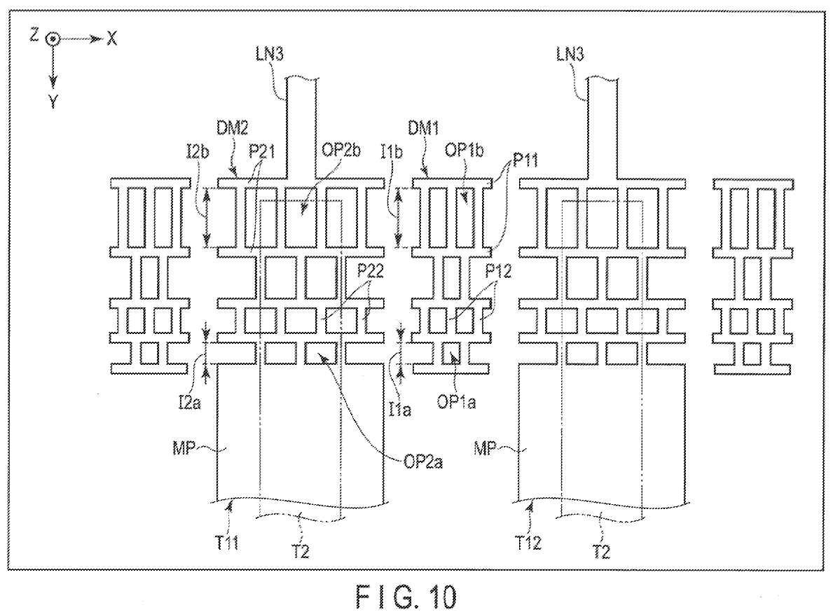

As described above, according to the first embodiment, a highly reliable display device can be obtained. Next, another example of the first embodiment will be described with reference to FIGS. 10 to 15.

FIG. 10 is a plan view of another example of the dam portion DM1. The example shown in FIG. 10 is different from that shown in FIG. 8 in that the openings OP1 vary in size along the second direction Y. More specifically, an opening OP1a is smaller than an opening OP1b. Here, along the second direction Y, the opening OP1a is closer to the main portion MP than the opening OP1b. In the example illustrated, the gap I1a between the portions P11 on a main portion MP side is smaller than the gap I1b between the portions P11 on a wiring line LN3 side. In other words, the length of the portions P12 on the main portion MP side is smaller than the length of the portions P12 on the wiring line LN3 side. On the other hand, the portions P12 are arranged along the first direction X at equal intervals.

In the example illustrated, the dam portions DM2 have a structure similar to that of the dam portions DM1. The openings OP2 of the dam portions DM2 varies in size along the second direction Y. More specifically, the opening OP2a is smaller than the opening OP2b. Here, the opening OP2a is closer to the main portion MP than the opening OP2b. In the example illustrated, the gap I2a between adjacent pair of portions P21 on the main portion MP side is smaller than the gap I2b between adjacent pair of portions P21 on the wiring line LN3 side. In other words, the length of the portions P22 on the main portion MP side is smaller than the length of the portion P22 on the wiring line LN3 side. On the other hand, the portions P22 are arranged along the first direction X at equal intervals.

Note that structure of the dam portions DM1 and DM2 is not limited to that of the example illustrated. For example, in the dam portions DM1, the gap between the portions P12 on the main portion MP side may be less than the gap between the portions P12 on the wiring line LN3 side. Alternatively, the gap between the portions P11 and the gap between the portions P12 may be different from each other along the second direction Y. This is also the case for the dam portions DM2.

In this example as well, advantages similar to those of the example shown in FIG. 8 can be obtained. Furthermore, according to this example, the coverage of the overcoat layer OC on the wiring line LN3 side can be improved by enlarging the opening OP1b on the wiring line LN3 side as compared to the opening OP1a on the main portion MP side. Therefore, it is possible to reliably cover the detection electrodes Rx and the wiring lines LN3 by the overcoat layer OC, and further to prevent the adhesion of the overcoat layer OC to the main portion MP.

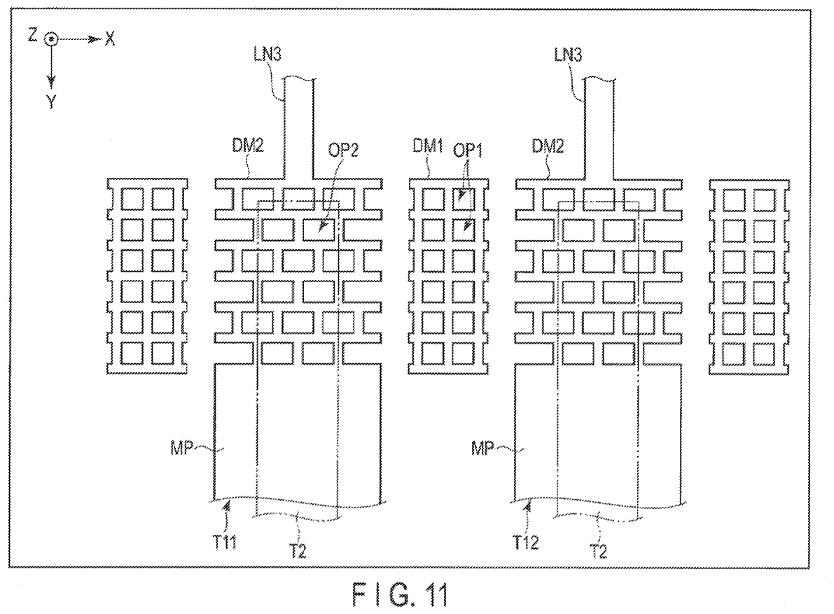

FIG. 11 is a plan view of another example of the dam portion DM1. The example shown in FIG. 11 is different from that shown in FIG. 8 in that the openings OP1 are linearly arranged along the second direction Y. The openings OP1 are larger than the openings OP2. In this example as well, advantages similar to those of the example shown in FIG. 8 can be obtained.

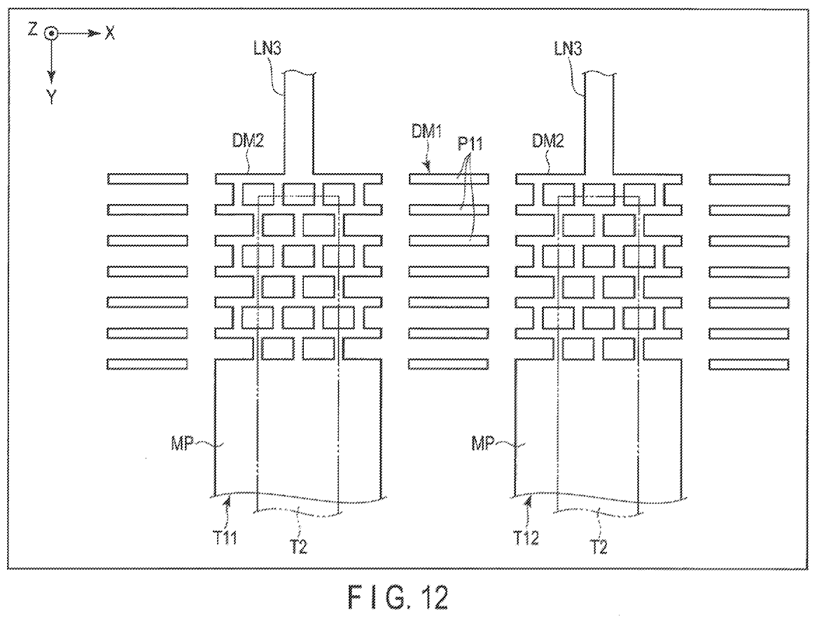

FIG. 12 is a plan view of another example of the dam portion DM1. The example shown in FIG. 12 is different from that shown in FIG. 8 in that the dam portions DM1 do not comprise a portion P12. That is, the dam portions DM1 are formed from a plurality of portions P11 arranged along the second direction Y. In this example as well, advantages similar to those of the example shown in FIG. 8 can be obtained. Furthermore, according to this example, the contact area between the overcoat layer OC and the base material 20 is increased, the detachment of the overcoat layer OC can be suppressed near the terminals T1.

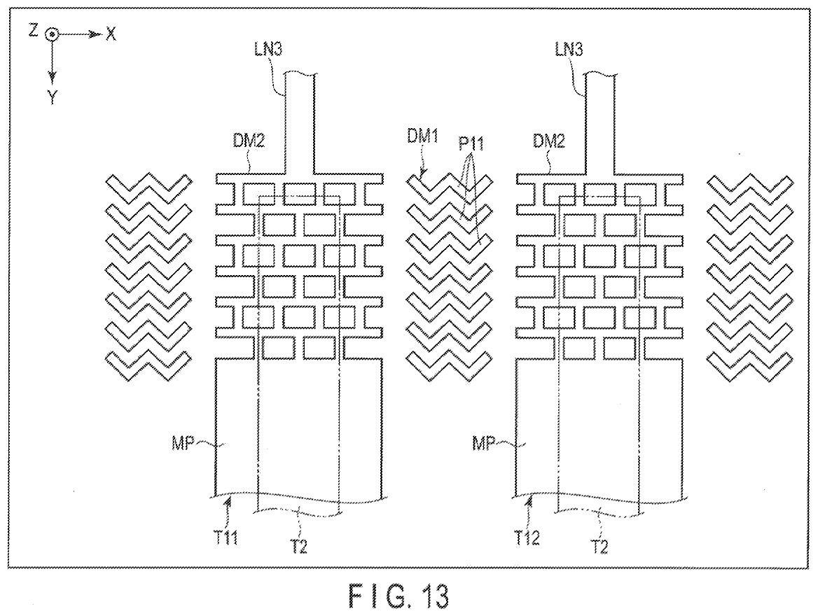

FIG. 13 is a plan view of another example of the dam portion DM1. The example shown in FIG. 13 is different from that shown in FIG. 12 in that the portions P11 are bent. In the example illustrated, the portions P11 are linearly bent, but they may be waved in an arc fashion. In this example as well, advantages similar to those of the example shown in FIG. 12 can be obtained.

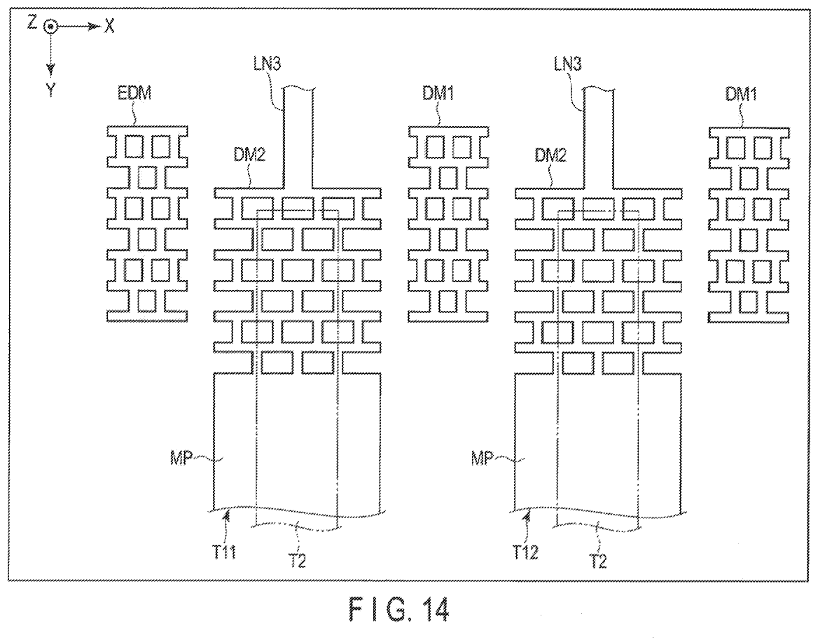

FIG. 14 is a plan view of another example of the dam portion DM1. The example shown in FIG. 14 is different from that shown in FIG. 8 in that the dam portions DM1 and the dam portions DM2 are arranged in a staggered manner. In the example illustrated, the dam portions are spaced from the main portion MP further than the dam portions DM2 along the second direction Y. In this example as well, advantages similar to those of the example shown in FIG. 8 can be obtained.

### Second Embodiment

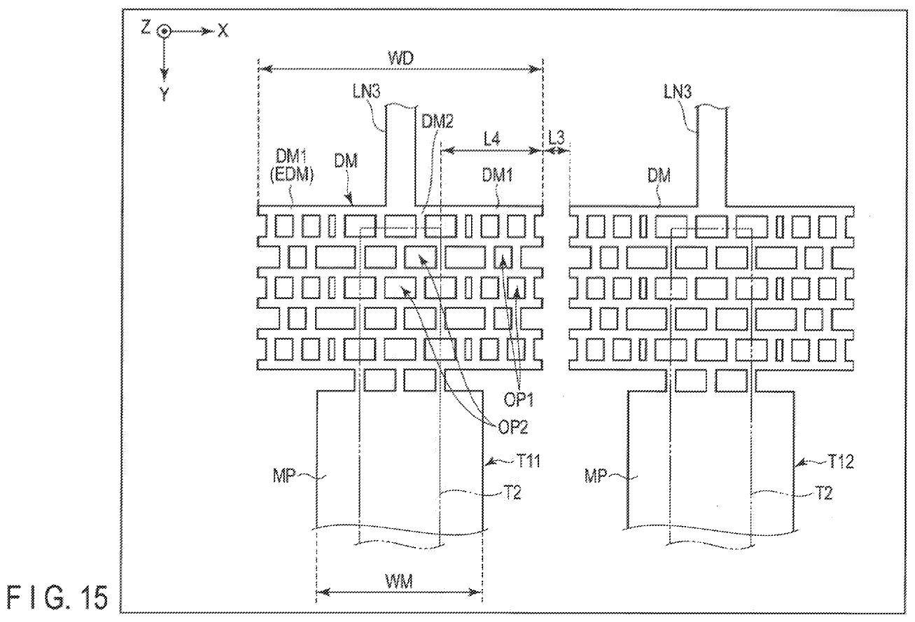

FIG. 15 is a plan view showing a configuration example of terminals T1 in a display device 1 according to the second embodiment. The second embodiment is different from the first embodiment in that dam portions DM1 are respectively connected to dam portions DM2. The dam portions DM1 and the dam portions DM2 constitute dam portions DM in terminals T1, respectively. The dam portions DM shown in FIG. 15 are equivalent to the structure shown in FIG. 8 in which the dam portions DM1 and the dam portions DM2 are connected respectively to each other. That is, the dam portions DM1 are formed in a mesh and comprises a plurality of openings OP1. The dam portions DM2 are formed in a mesh and comprises a plurality of openings OP2. In this embodiment, a width WD of the dam portions DM along the first direction X is greater than a width WM of the main portion MP. The dam portions DM extend to outer sides of both end portions of the main portion MP along the first direction X.

A terminals T11 and a terminals T12, or more specifically, each adjacent pair of dam portions DM, are spaced from each other at least by a distance L3. The distance L3 is such a distance that the insulation between each adjacent pair of terminals T1 is maintained when mounting the wiring substrate 52 on the display panel 2 via an anisotropic conductive film ACF. The distance L3 is, for example, about 20 μm. Moreover, the distance L4 shown in FIG. 15 is a distance between ends of the terminals T2 and end portions of the dam portion DM along the first direction X. The distance L4 is defined by the alignment accuracy of the wiring substrate 52 and the dimensional error of the wiring substrate 52.

In this embodiment as well, the mesh structure of dam portions DM is finer than the pitch of ink jet nozzles used to form the overcoat layer OC. Therefore, when the resin material discharged from the ink jet nozzles covers the dam portions DM, the tension acts to suppress the expansion of the resin material. According to this embodiment, the dam portions DM extend to outer sides of the main portion MP along the first direction X, and thus spreading of the overcoat layer OC over the region between adjacent main portions MP can be suppressed. As a result, adhesion of the overcoat layer OC to the main portion MP can be suppressed. That is, the effective connection area between the terminals T1 and the wiring substrate 52 is secured. Thus, the adhesion of the display panel 2 and the wiring substrate 52 can be improved and the connection resistance between the terminals T1 and the terminals T2 can be suppressed. Thus, a highly reliable display device can be provided.

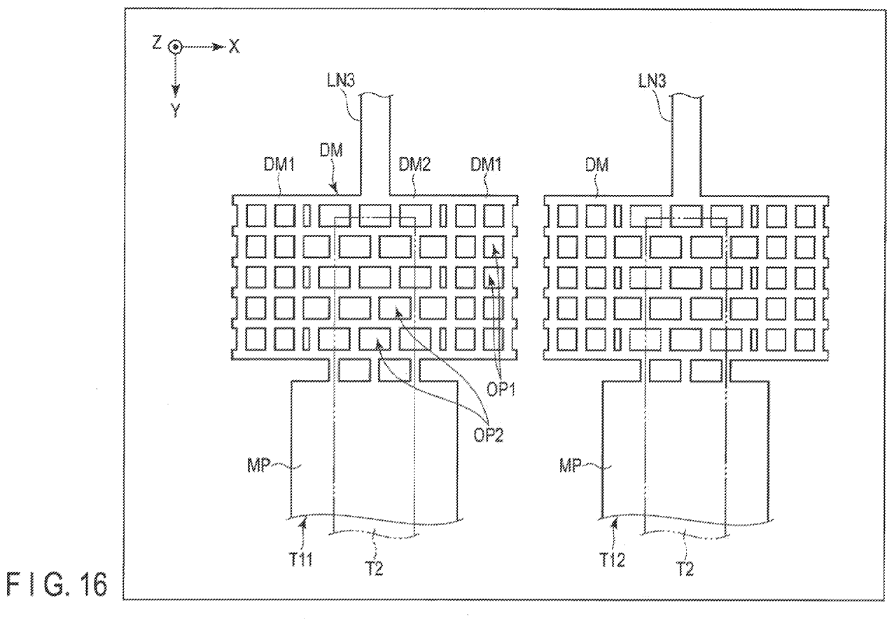

Next, another example of the second embodiment will be described with reference to FIGS. 16 to 18. FIG. 16 is a plan view showing another example of the terminals T1. The example shown in FIG. 16 is different from that shown in FIG. 15 in that openings OP1 are arranged along the second direction Y. That is, the dam portions DM shown in FIG. 16 are equivalent to the structure in which the dam portions DM1 and the dam portions DM2 shown in FIG. 11 are respectively connected to each other. In this example as well, advantages similar to those of the example shown in FIG. 15 can be obtained.

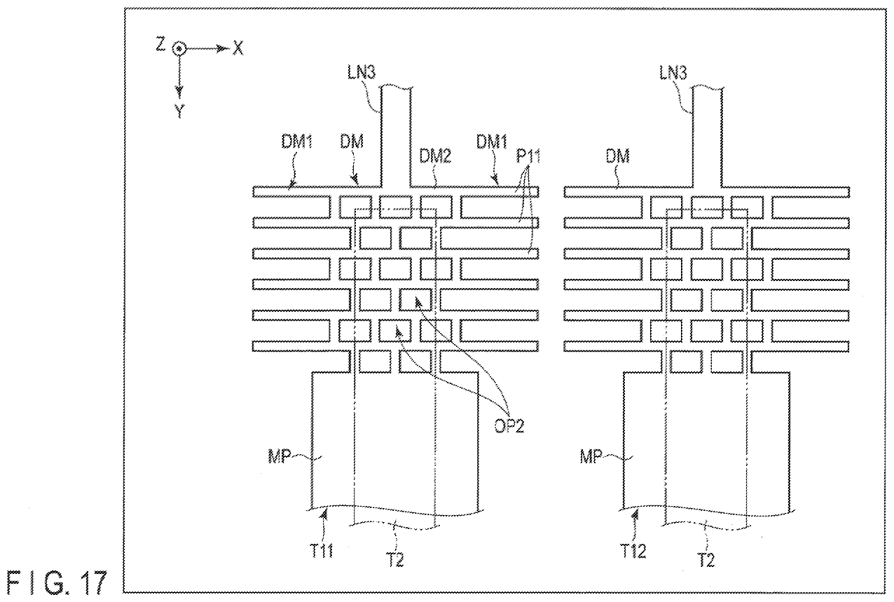

FIG. 17 is a plan view showing another example of the terminals T1. The example shown in FIG. 17 is different from that shown in FIG. 15 in that the dam portions DM1 comprise only a portion P11 and do not comprise a portion P12. That is, the dam portions DM shown in FIG. 17 are equivalent to the structure in which the dam portions DM1 and the dam portions DM2 shown in FIG. 12 are connected respectively to each other. In this example as well, advantages similar to those of the example shown in FIG. 15 can be obtained.

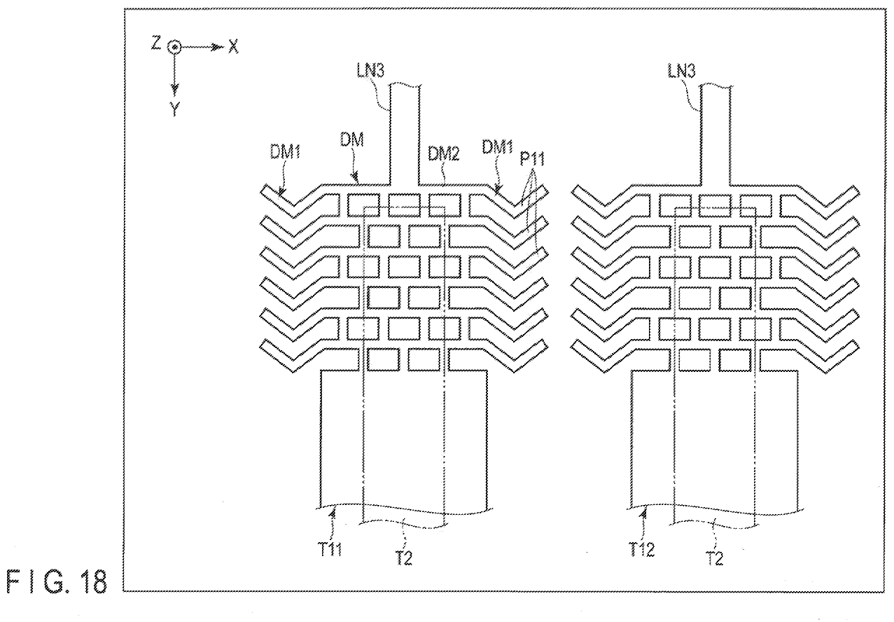

FIG. 18 is a plan view showing another example of the terminals T1. The example shown in FIG. 18 is different from that shown in FIG. 17 in that the portions P11 are bent. That is, the dam portions DM shown in FIG. 18 are equivalent to the structure in which the dam portions DM1 and the dam portions DM2 shown in FIG. 13 are connected respectively to each other. In this example as well, advantages similar to those of the example shown in FIG. 15 can be obtained.

### Third Embodiment

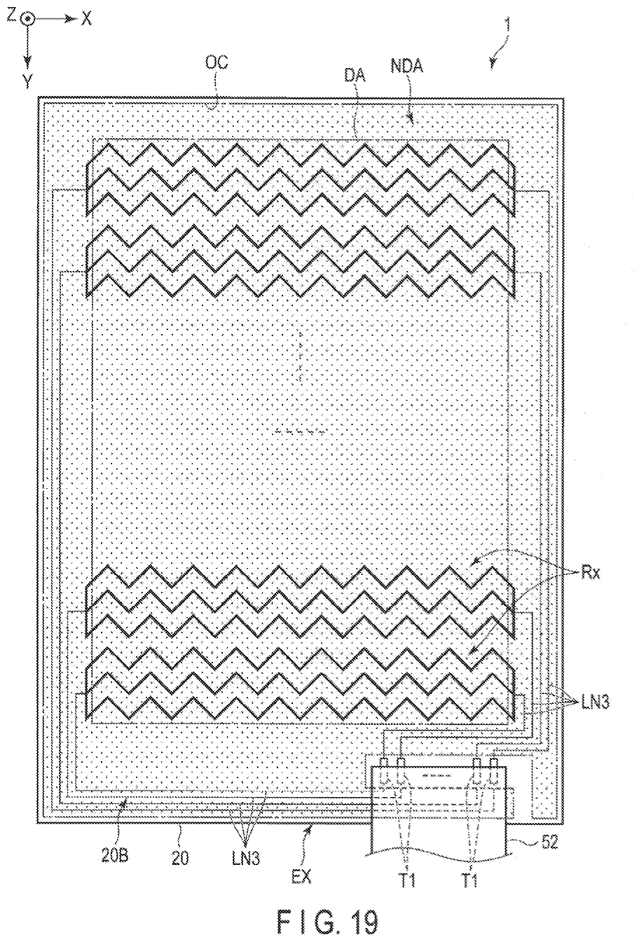

FIG. 19 is a plan view showing an example of a display device 1 according to the third embodiment. FIG. 19 is a plan view schematically showing the elements provided on the second surface 20B of the base material 20. The third embodiment is different from the first embodiment in that the wiring lines LN3 are connected to both end portions of the terminals T1. In the example illustrated, the wiring lines LN3 drawn out from ends (for example, on a right-hand side of the figure) of the detection electrodes Rx are connected to ends of the terminals T1 through a right-hand side portion (in the drawing) of the non-display area NDA. The wiring lines LN3 drawn out from other ends (for example, on a left-hand side in the drawing) of the detection electrodes Rx are connected to the other ends of the terminals T1 via an end EX side portion of the non-display area NDA.

The overcoat layer OC covers substantially the entire region of the second surface 20B except for the region where the terminals T1 are formed. In the example illustrated, the region where the overcoat layer OC is not formed is substantially into an L shape.

FIG. 2 is an enlarged view of a vicinity of a wiring substrate 52 shown in FIG. 19. The overcoat layer OC also covers both end portions of the terminals T1 to which the wiring lines LN3 are respectively connected. In the example illustrated, the overcoat layer OC also covers both end portions of the terminal T2. Therefore, overlap areas OL where the overcoat layer OC and the anisotropic conductive film ACF overlap each other are formed in both end portions of the terminal T1.

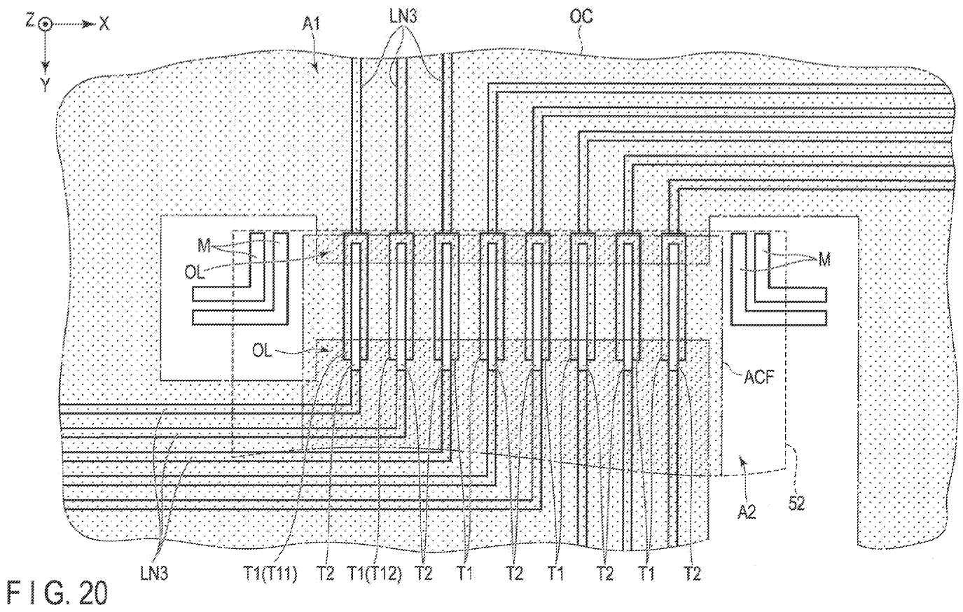

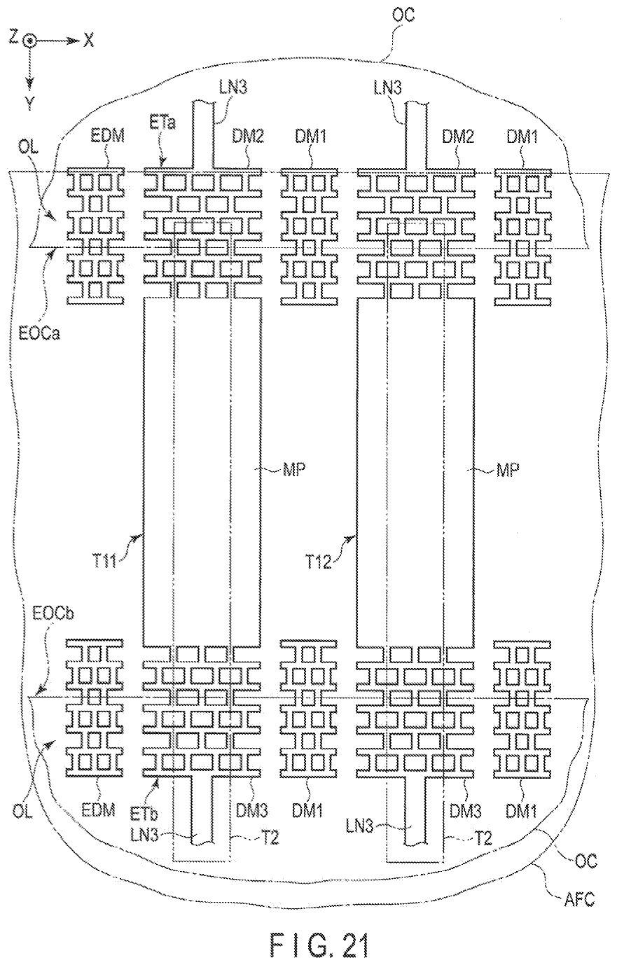

FIG. 21 is an enlarged plan view showing the terminal T11 and the terminal T12 shown in FIG. 20. In this embodiment, the terminals T1 each include, in addition to the dam portion DM2, a dam portion DM3. A main portion MP is located between the dam portion DM2 and the respective dam portion DM3. Moreover, a dam portion DM1 is provided not only between adjacent dam portions DM2, but also between adjacent dam portions DM3. In the example illustrated, the structure of the dam portion DM3 is similar to that of the dam portion DM2, but it may be different.

Along the second direction Y, the overcoat layer OC provided on an end portion ETa side of the terminal T1 covers all of the wiring lines LN3, and partially covers the dam portions DM1 and DM2. That is, the end portion EOCa of the overcoat layer OC, located on an end portion ETa side, is located in the range where the dam portions DM1 and DM2 are formed, along the second direction Y. Moreover, along the second direction Y, the overcoat layer OC provided in the end ETb side of the terminal T1 covers all of the wiring lines LN3, and partially covers the dam portions DM1 and DM2. That is, the end EOCb of the overcoat layer OC, located on the end ETb side is located in the range where the dam portions DM1 and DM3 are formed, along the second direction Y.

In this embodiment as well, the dam portions DM1 are each provided between adjacent terminals T1, and therefore advantageous effects similar to those of the first embodiment can be obtained. Further, as shown in FIG. 21, in the structure in which the overcoat layer OC is formed in both sides of the end portions ETa and ETb of the terminal T1, the range of the overlap area OL along the second direction Y is large. Therefore, the embodiment in which the accuracy of the position control of the end portions EOCa and EOCb can be improved is useful to reduce the width of the frame.

Note that the structure of the dam portions DM1 is not limited to that of the example illustrated. Moreover, as discussed in the second embodiment, the dam portions DM1 and the dam portions DM2 may be connected respectively to each other, or the dam portions DM1 and the dam portions DM3 may be connected respectively to each other.

### Fourth Embodiment

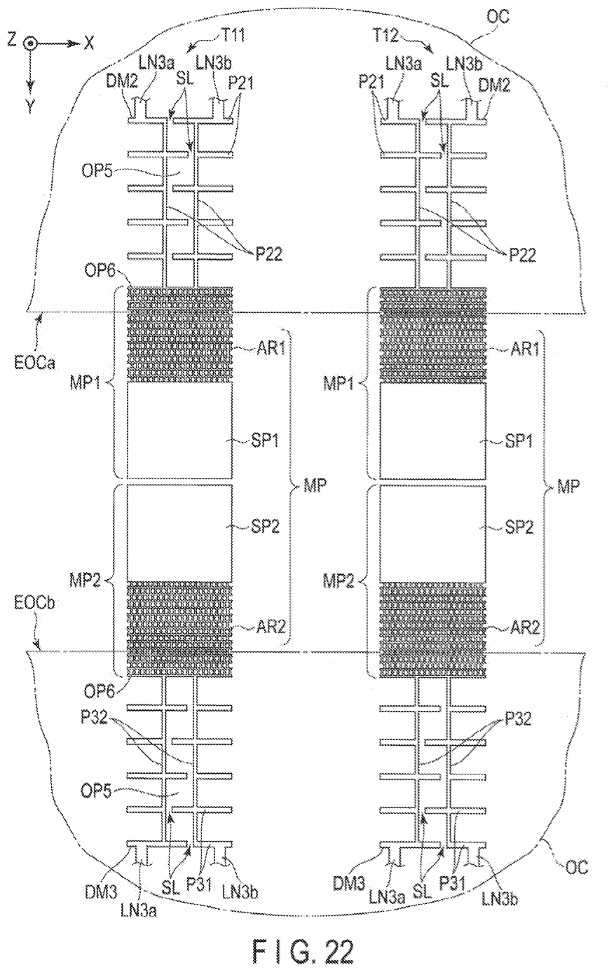

FIG. 22 is a plan view showing a configuration example of terminals T1 of a display device 1 according to the fourth embodiment. The fourth embodiment is different from the third embodiment in that a dam portion DM2 and a dam portion DM3 each comprise a slit SL. Note that in the fourth embodiment, a dam portion DM1 may not necessarily be formed between a terminal T11 and a terminal T12.

The dam portion DM2 is located between a group of the wiring lines LN3a and LN3b and the main portion MP, and it is connected thereto. The dam portion DM2 includes a portion P21 extending along the first direction X and a portion P22 extending along the second direction Y. The portion P21 comprises a slit SL. The dam portion DM3 is located between the group of the wiring lines LN3a and LN3b and the main portion MP, and it is connected thereto. The dam portion DM3 includes a portion P31 extending along the first direction X and a portion P32 extending along the second direction Y. The portion P31 comprises a slit SL. Note that the slit SL may be formed in any parts of the portion P21 and the portion P31. Moreover, each of the wiring lines LN3a and LN3b is connected to one wiring line LN3 such as shown in FIG. 21.

The main portion MP is located between the dam portion DM2 and the dam portion DM3 and formed to be integrated with the dam portion DM2 and the dam portion DM3 as one body. In the example illustrated, the main portion MP is divided into a first portion MP1 and a second portion MP2. The first portion MP1 is connected to the dam portion DM2. The second portion MP2 is connected to the dam portion DM3. The first portion MP1 includes a smooth region SP1 and a network region AR1 located between the smooth region SP1 and the dam portion DM2. The dam portion DM2 comprises an opening OP5. The mesh region AR1 comprises an opening OP6 smaller in size than the opening OP5. The second portion MP2 includes a smooth region SP2 and a mesh region AR2 located between the smooth region SP2 and the dam portion DM3. The dam portion DM3 comprises an opening OP5. The mesh region AR2 comprises an opening OP6 smaller in size than the opening OP5. An overcoat layer OC is provided to overlap the dam portion DM2 and the mesh region AR1. Moreover, the overcoat layer OC overlaps the dam portion DM3 and the mesh region AR2.

In this embodiment, the dam portion DM2 and the dam portion DM3 each comprises a slit SL in the portion P21 and the portion P31. With this structure, it is possible to inhibit the resin material from being excessively dammed up by the portions DM2 and DM3. Thus, exposure of the wiring lines from the overcoat layer OC can be inhibited to suppress corrosion of the wiring lines. On the other hand, due to the slits SL thus formed, a great amount of resin material may undesirably flows into the main portion MP. Here, by forming mesh regions AR1 and AR2 of a pattern more precise than that of the dam portions DM2 and DM3, it is possible to inhibit an excessive amount of resin material from flowing into the main portion MP. That is, an effective connection area between the display panel 2 and the wiring board 52 is thus secured, and therefore the adhesion between the display panel 2 and the wiring board 52 can be improved and the increase in the connection resistance between the terminal T1 and the terminal T2 can be suppressed. In this manner, a highly reliable display device can be provided. Moreover, the variation in the position of end portions EOCa and EOCb of the overcoat layer OC can be reduced. More specifically, along the second direction Y, the end portion EOCa is controlled to be located within a zone where the dam portion DM2 is formed or within a zone where the mesh region AR1 is formed. Similarly, along the second direction Y, the end portion EOCb is controlled to be located within a zone where the dam portion DM3 is formed or within a zone where the mesh region AR2 is formed.

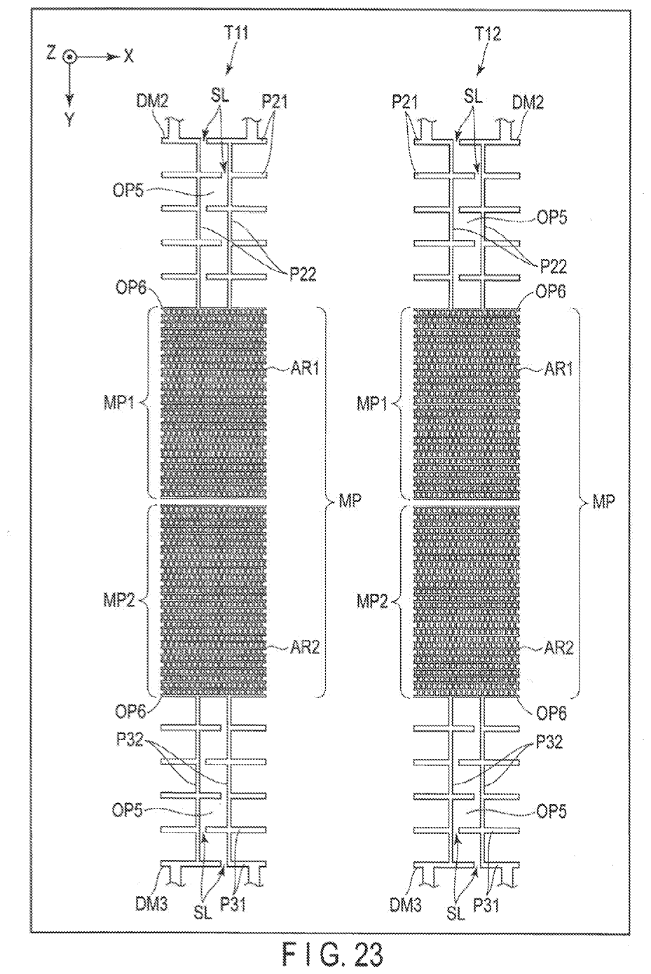

FIG. 23 is a plan view showing another example of the main portion MP. The example shown in FIG. 23 is different from the example shown in FIG. 22 in that the entire main portion MP is formed into a mesh form. In other words, the mesh region AR1 corresponds to the entire region of the first portion MP1. Further, the mesh region AR2 corresponds to the entire region of the second portion MP2. Thus, the width of each of the mesh regions AR1 and AR2 along the second direction Y is expanded to make it easy to dam up the overcoat layer, and thus the connection area of the main portion MP can be secured. The dam portions DM2 and DM3 each comprise an opening OP5, and the mesh regions AR1 and AR2 each comprise an opening OP6 smaller in size than the opening OP5.

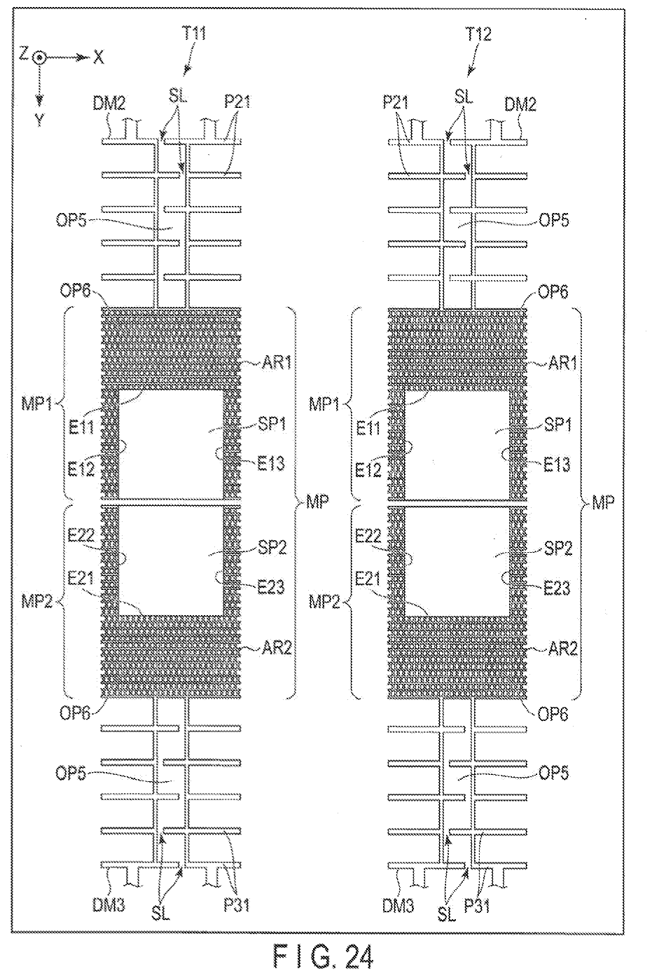

FIG. 24 is a plan view showing another example of the main portion MP. The example shown in FIG. 24 is different from the example shown in FIG. 22 in that the mesh regions AR1 and AR2 are formed to surround the smooth regions SP1 and SP2, respectively. The first portion MP1 includes the smooth region SP1 and the mesh region AR1. The smooth region SP1 comprises a first edge E11, a second edge E12 and a third edge E13. The mesh region AR1 surrounds the smooth region SP1 along the first edge E11, the second edge E12 and the third edge E13. The second portion MP2 includes the smooth region SP2 and the mesh region AR2. The smooth region SP2 comprises a first edge E21, a second edge E22 and a third edge E23. The mesh region AR2 surrounds the smooth region SP2 along the first edge E21, the second edge E22 and the third edge E23.

As shown in FIG. 24, the mesh region AR1 is formed along the second edge E12 and the third edge E13, and with this structure, it is possible to suppress the resin material overflowing from the dam portion DM2 into the mesh region AR1, from further flowing to the side of the second edge E12 and third edge E13. Similarly, the mesh region AR2 is formed along the second edge E22 and the third edge E23, and with this structure, it is possible to suppress the resin material overflowing from the dam portion DM3 into the mesh region AR2, from further flowing into the side of the second edge E22 and third edge E23. Note that the dam portions DM2 and DM3 each comprises the opening OP5, and the mesh regions AR1 and AR2 each comprise the opening OP6 smaller in size than the opening OP5.

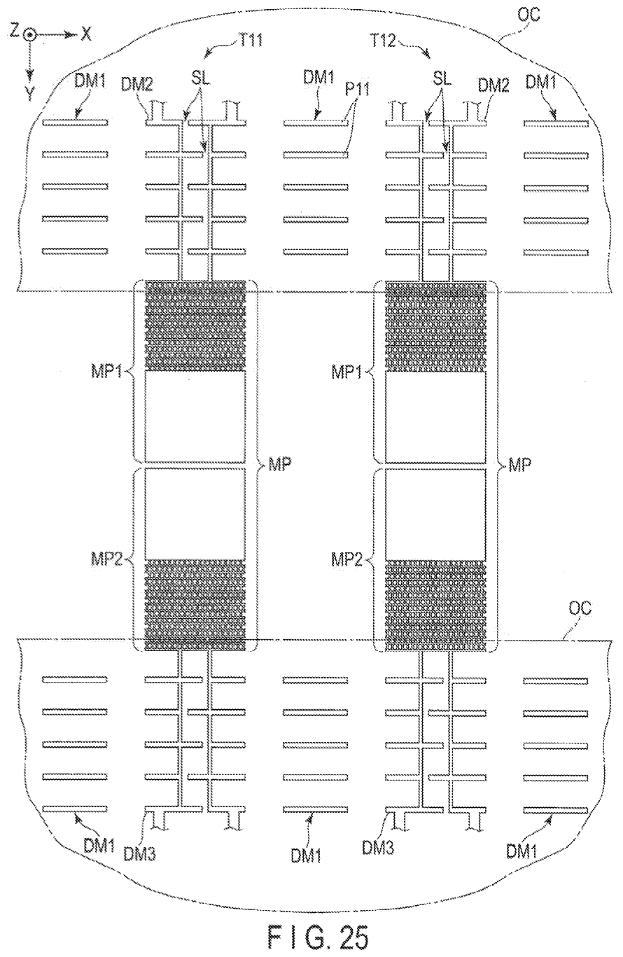

FIG. 25 is a plan view showing another example of the fourth embodiment. The example shown in FIG. 25 is different from the example shown in FIG. 22 in that dam portions DM1 are formed here. The dam portions DM1 are each located between a terminal T11 and a respective terminal T12. More specifically, a dam portion DM1 is formed between an adjacent pair of dam portions DM2, and another dam portion DM1 is formed between an adjacent pair of dam portions DM3. In the example illustrated, the dam portions DM1 are each formed from a plurality of portions P11 extending along the first direction X and arranged along the second direction Y. The dam portions DM1 overlap the overcoat layer OC in plan view. Note that the structure of the dam portions DM1 is not limited to that described above, but any of the structures of the portions DM1 discussed in the first embodiment may be applied.

In each of the above-described embodiments, the terminals T11 are equivalent to the first terminals, and the terminals T12 are equivalent to the second terminals. The dam portions DM1 are equivalent to the first pattern for a dam, the dam portions DM2 are equivalent to the second pattern, and the dam portions DM3 are equivalent to the third pattern. The wiring lines LN3 connected to the terminals T11 are equivalent to the first wiring lines, and the wiring lines LN3 connected to the terminals T12 are equivalent to the second wiring lines. The overcoat layer OC is equivalent to the resin layer. The openings OP1 or openings OP1a are equivalent to the first openings. The openings OP1b are equivalent to the second openings. The openings OP2 or openings OP2a are equivalent to the third openings. The openings OP2b are equivalent to the fourth openings. The openings OP5 are equivalent to the fifth openings. The openings OP6 are equivalent to the sixth openings.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A electric circuit board comprising:
a base material;
a first terminal and a second terminal formed on the base material;
a first wiring formed on the base material and connected to the first terminal;
a second wiring formed on the base material and connected to the second terminal;
a resin layer covering the first wiring and the second wiring; and
a first pattern formed on the base material,
the first terminal and the second terminal being arranged along a first direction,
the first pattern being located between the first terminal and the second terminal, and
the first pattern overlapping the resin layer in plan view.

2. The electric circuit board of claim 1, wherein
the first terminal comprises a main portion and a second pattern,
the second pattern is located between the first wiring and the main portion and is formed to be integrated with the main portion.

3. The electric circuit board of claim 2, wherein
the first terminal further comprises a third pattern, and
the main portion is located between the second pattern and the third pattern, and is formed to be integrated with the second pattern and the third pattern.

4. The electric circuit board of claim 2, wherein
the first pattern comprises a first opening and a second opening spaced from the main portion than the first opening, and
the first opening is smaller than the second opening.

5. The electric circuit board of claim 3, wherein
the second pattern comprises a third opening and a fourth opening spaced from the main portion than the third opening, and
the third opening is smaller than the fourth opening.

6. The electric circuit board of claim 2, wherein
the first pattern and the second pattern are arranged in a staggered fashion in plan view.

7. The electric circuit board of claim 2, wherein
the first pattern and the second pattern are arranged along the first direction.

8. The electric circuit board of claim 2, wherein
the first pattern is not connected to the second pattern.

9. The electric circuit board of claim 2, wherein
the first pattern comprises a first opening,
the second pattern comprises a third opening, and
the first opening is smaller than the third opening.

10. The electric circuit board of claim 2, wherein
the first pattern comprises first openings linearly arranged, and
the second pattern comprises third openings arranged in a staggered fashion.

11. The electric circuit board of claim 2, wherein
the first pattern is formed from first portions arranged along a second direction crossing the first direction, and
the second pattern is formed in a mesh.

12. The electric circuit board of claim 1, wherein
the first pattern comprises first portions each extending along the first direction.

13. The electric circuit board of claim 11, wherein
the first pattern comprises second portions extending along a second direction crossing the first direction, and
a first gap between an adjacent pair of the first portions and a second gap of an adjacent pair of the second portions each are 50 μm or less.

14. The electric circuit board of claim 1, wherein
the first wiring is a first detection electrode, and
the second wiring is a second detection electrode.

15. A electric circuit board comprising:
a base material;
a first terminal formed on the base material;
a first wiring formed on the base material and connected to the first terminal; and
a resin layer covering the first wiring,
the first terminal comprising a main portion and a second pattern,
the second pattern being located between the first terminal and the main portion, and is formed to be integrated with the main portion, and comprising a plurality of fifth openings,
the main portion comprises a first area, and a second area located between the first area and the second pattern,
the second area has a plurality of sixth openings smaller than the fifth openings,
the fifth openings are formed of first portions extending along a first direction and second portions extending along a second direction crossing the first direction,
the first portions has slit at a position between an adjacent pair of the fifth openings.

16. The electric circuit board of claim 15, wherein
the first area has a plurality of the sixth openings.

17. The electric circuit board of claim 15, wherein
the second area surrounds the first area.

18. The electric circuit board of claim 15, wherein
the first terminal further comprises a third pattern,
the main portion is located between the second pattern and the third pattern,
the third pattern is formed to be integrated with the main portion, and comprising a plurality of fifth openings,
the fifth openings are formed of third portions extending along the first direction and fourth portions extending along the second direction,
the third portions has slit at a position between an adjacent pair of the fifth openings.

19. The electric circuit board of claim 15, further comprising:
a second terminal formed on the base material,
a second wiring formed on the base material and connected to the second terminal; and
a first pattern formed on the base material,
wherein
the first terminal and the second terminal arranged along the first direction,
the first pattern is located between the first terminal and the second terminal and overlap the resin layer in plan view.

20. The electric circuit board of claim 19, wherein
the first pattern is formed a plurality of fifth portions extending along the first direction and arranged along the second direction.
